(19) United States
(12) Patent Application Publication
(10) Pub. No.: US 2008/0303610 A1
(43) Pub. Date: Dec. 11, 2008

(54) TUNED FILTERS WITH ENHANCED HIGH FREQUENCY RESPONSE

(75) Inventors: Joseph A. Zennamo, JR., Skaneateles, NY (US); Bradford R. Spoor, Weedsport, NY (US); William Louise, North Syracuse, NY (US); Gary J. Clark, Constantia, NY (US)

Correspondence Address: BURR & BROWN, PO BOX 7068, SYRACUSE, NY, 13261-7068, US

(73) Assignee: Eagle Comtronics, Inc., Liverpool, NY (US)

(21) Appl. No.: 11/759,423

(22) Filed: Jun. 7, 2007

(51) Int. Cl. H03H 7/01

(52) U.S. Cl. 333/175; 333/185

(57) ABSTRACT

A tuned filter having enhanced high frequency response includes a circuit board having first and second opposed major surfaces and first and second opposing sides. The opposed major surfaces are substantially parallel to a single plane and are bisected by a longitudinal axis. The first and second opposing sides are substantially parallel to the longitudinal axis. An input terminal and an output terminal are connected to the single circuit board. A filter section is associated with the first major surface. At least two ground paths are associated with the second major surface. One of the ground paths extends along a portion of the first side, and another one of the ground paths extends along a portion of the second opposing side. An isolation region separates the at least two ground paths, and extends along the longitudinal axis.

### FIELD OF THE INVENTION

The invention relates to a radio frequency filter that can operate in cable television systems having bandwidth spanning a range from 5 MHz to 3 GHz.

### BACKGROUND OF THE INVENTION

Receiving electronic services provided by others through a coaxial cable is not new. In the early years, individuals set up large, expensive antennas within a community to receive clear television signals from distant television transmitters, which may not be accessible to other's in the community. To help fund these expensive antennas, the individuals split the radio frequency (RF) television or radio signals received by the antenna into multiple outlets allowing others the opportunity to receive the clearer RF signals available from the larger, more expensive antenna. In return for this benefit, consumers of the signals, typically called subscribers, paid the provider for the signals provided.

As a result of demand, these providers outfitted entire neighborhoods and communities with an infrastructure of coaxial cables to pass the signal from the provider's antenna, more typically referred to as the head end, to the home of the subscriber. For example, a main signal transmission line was provided along a street, and splitters, typically called taps, were provided at intervals along the main signal transmission line to allow individual lines to be connected between the main signal transmission line and the house. If a subscriber purchased the signals from the provider, a technician of the provider would physically make the connection between the house and the main signal transmission line at a tap closest to the subscriber. Because the tap was located a large distance from the ground on a telephone pole or the like, non-subscribers were generally dissuaded from making the connection themselves to effectively steal the signals without paying for the service.

In later years, the providers broadened the types of signals available to include premium signals, including movies and other content, which were offered to the subscribers at an additional cost over the traditional signals. Of course, many subscribers were willing to purchase the premium content, while many others chose not to incur the additional costs. Because all the signals (including those to be sold at an additional cost) had to be included in the main signal transmission line at the street level, the premium signals had to be blocked to those subscribers who did not pay the additional fees. One such method of restricting access to the premium signals was through the use of a tuned filter or trap installed between the main signal transmission line and the house. The tuned filters effectively blocked those signals for which the subscriber did not pay or, in other words, allowed only the paid signals to reach the subscriber.

The amount of channels originally offered by the providers fit nicely within a bandwidth spectrum spanning 5 MHz-300 MHz, with each analog television channel occupying 6 MHz. Because of an increasing number of channels desired by subscriber, the upper end of the bandwidth spectrum was expanded in 1982 to approximately 520 MHz allowing an additional 36 channels.

More recently, in the late 1990's, new demands were placed on the providers to raise the upper end of the bandwidth spectrum from 520 MHz to 1000 MHz (1 GHz). As discussed above, the signals originally offered by provider's were in the form of television or radio channels. Due to industry standards, each channel required a specific amount of frequency bandwidth, 6 MHz. Through digital compression, the providers were able to squeeze six to ten standard definition television channels into the 6 MHz bandwidth originally required by one analog television channel. This benefit quickly diminished with the growing popularity of high definition television, which requires significantly more bandwidth to transmit than a standard definition television channel. Further, with subscribers demanding ever faster internet access, providers realized that their existing infrastructure, including the main signal transmission line, could be used to transmit and receive data and internet signals at a much higher speed than a traditional telephone line. As one can easily imagine, the traditionally used range of 5 MHz-520 MHz began filling up to such a degree that providers wanted to broaden the frequency bandwidth capacity of their systems to include up to 1 GHz, allowing the providers to offer more premium content and collect more revenue using their previously installed infrastructure. While much of the existing infrastructure, such as the main signal transmission line itself, is able to accommodate the additional frequency bandwidth, many of the other passive components, such as the taps and the filters, could not operate at the frequency bandwidth range between 520 MHz and 1 GHz.

It was found, however, that the original tuned filters, which are used to allow access to only those signals purchased, failed to function properly when the frequency bandwidth was extended to 1 GHz. Signals having a frequency in the range between 520 MHz and 1 GHz are more easily attenuated or degraded when compared to signals having lower frequencies. It was found that when tuned filters, designed to function at frequencies below 520 MHz, were used to pass the higher frequencies, the resulting high frequency response was poor at best. As one can easily imagine, any amount of signal attenuation, which is then multiplied by the number of tuned filters present, causes significant signal quality issues for the subscriber, and, in turn, causes significant profit losses for the provider.

As disclosed in U.S. Pat. No. 5,770,983 to Zennamo et. al., incorporated herein by reference, significant changes were required to the placement of the internal components of the filter to allow signals in the range between 520 MHz and 1 GHz to pass through the filter without signal loss or distortion. As can be seen in FIG. 4 of the '983 patent, significant loss and distortion occurred in the original filters at frequencies above 520 MHz. The tuned filter of the '983 patent effectively extended the high frequency response of the tuned filters such that the additional bandwidth could be efficiently utilized without attenuation losses induced by the filters, A cross-section of a tuned filter in accordance with the '983 patent is shown in FIG. 1 and is discussed in further detail below.

In more recent years, the signal providers have found even more uses for the signals that can be provided through much of their existing infrastructure. These uses include providing signals relating to home security monitoring, even faster data and internet services, and telephone services. Not surprisingly, the providers are now running out of signal bandwidth availability in the 5 MHz to 1 GHz to offer these additional services, which increase income and profitability. As a result, the providers are increasingly looking toward adding additional bandwidth availability stretching beyond the current 1 GHz limit to 3 GHz. Again, while the main signal transmission line is likely able to accommodate the additional bandwidth, the passive devices connected to the main signal transmission line, such as the taps and the tuned filters, cannot accommodate these additional frequencies without attenuating and distorting the higher frequencies.

Rather than expand into the higher frequency bands to meet the consumer's demands, the providers could rely on the current technology and add duplicate infrastructure and divide the services across the duplicate devices. This option results, however, in many undesirable results such as additional cables to purchase and maintain. Due to the enormous cost alone, this approach is impractical. Accordingly, new passive devices, including tuned filters, must be designed that have sufficient high frequency response and can pass signals having frequencies greater that 1 GHz without attenuation and distortion.

### SUMMARY OF THE INVENTION

An object of the present invention is to overcome the problems with passive devices, such as tuned filters, caused by adding additional bandwidth availability stretching beyond the current 1 GHz limit to 3 GHz. It is another object of the present invention to allow a signal provider to use passive devices such as tuned filters with their existing infrastructure after the remaining infrastructure is updated to allow the addition of bandwidth stretching beyond the current 1 GHz limit to 3 GHz.

In accordance with one embodiment of the present invention, a tuned filter is provided that includes a single circuit board having first and second opposed major surfaces and first and second opposing sides. The opposed major surfaces are substantially parallel to a single plane and are bisected by a longitudinal axis, and the first and second opposing sides are substantially parallel to the longitudinal axis. An input terminal is connected to the circuit board with the input terminal having an axis extending substantially parallel to the longitudinal axis. An output terminal is connected to the single circuit board with the output terminal having an axis extending substantially parallel to the longitudinal axis. A filter section is associated with the first major surface. At least two ground paths are associated with a second major surface. One of the ground paths extends along a portion of the first opposing side, and another one of the ground paths extends along a portion of the second opposing side. An isolation region separates the at least two ground paths and extends along the longitudinal axis.

The resultant tuned filter has significantly less parasitic or fringe capacitance that can attentuate frequencies within the bandwidth spectrum up to 3 GHz. Further, the resultant tuned filter allows a signal provider to selectively pass or block RF signals to a subscriber in a manner desired by the signal provider.

Preferably, the tuned filter maintains adequate separation between separate filter circuits within the filter section so as to maintain the desired blockage or passage of RF signals. According to one embodiment of the present invention, the tuned filter further includes at least one inductive contact connecting the at least two ground paths. The inductive contact spans the isolation region and extends along the second major surface. According to one embodiment of the present invention, the inductive contact is a metallic wire that directly connects the at least two ground paths and has a continuous cross-section throughout its length between the at least two ground paths and the inductive contact is arranged at an angle incident to the longitudinal axis. According to another embodiment of the present invention, the tuned filter includes at least two inductive contacts that are connected to a common point on one of the grounding paths.

Preferably, the ground paths are electrically connected to an enclosure to provide sufficient grounding and isolation between individual filter circuits. According to one embodiment of the present invention, the tuned filter includes a plurality of grounding means attached to the single circuit board along the first and second opposing sides of the single circuit board, wherein at least one grounding means is directly connected to each of the grounding paths. According to one embodiment of the present invention, the grounding means are grounding clips, the grounding clips having a width of at least 0.070″ and a thickness of approximately 0.010″. According to another embodiment of the present invention, the grounding means contacts the circuit board with an area at least 0.007 in².

Preferably, the tuned filter includes discrete components allowing for easy modification and designs of the desired filter characteristics, and to allow specific placement of the individual components in an effort to reduce parasitic or fringe capacitance and increase the high frequency response of the tuned filter. According to one embodiment of the present invention, the filter section includes a plurality of discrete capacitor elements. Preferably, each capacitor element is associated with the first major surface above a respective ground path. According to another embodiment of the present invention, the filter section includes a plurality of discrete inductive elements. Preferably, each inductive element is associated with the first major surface above the isolation region separating the at least two ground paths.

Preferably, the tuned filter is made such that individual components can be adjusted at the time of assembly to account for variation in the individual parts of the tuned filter and to adjust the tuned filter in accordance with consumer demands. According to one embodiment of the present invention, at least one of the inductive elements includes tuning means for varying the inductance of the inductive element. Preferably, the tuning means is actuated along a direction perpendicular to the first and second surfaces.

Preferably, the inductive elements are sized such that they resist the creation of multiple resonances in the high frequency pass band of the tuned filter. According to one embodiment of the present invention, the filter section includes at least one inductive element that is an airwound inductor and at least one inductive element that is a wirewound chip inductor connected in series with the airwound inductor.

Preferably, the tuning filter is protected from access by people other than the signal provider so that appropriate access is maintained and reliability of the tuned filter is insured. According to one embodiment of the present invention, the tuned filter includes a conductive housing encircling the circuit board, the output terminal, and the input terminal. The conductive housing is electrically connected to each of the ground paths. Preferably, the conductive housing is cylindrical, and a central axis of the cylinder is substantially parallel with the longitudinal axis of the single circuit board.

Preferably, the impedance of the input terminal and the output terminal are matched to further extend the high frequency response of the tuned filter. According to one embodiment of the present invention, the tuned filter includes a series inductive impedance located at an end of the output terminal adjacent the circuit board and a shunt capacitance to ground after the inductive impedance. According to one embodiment of the present invention, the series inductive impedance is an increased outer conductor size and/or an additional physical inductor, and the shunt capacitance an increased pad size of the output terminal on the circuit board and/or at least one physical capacitor.

Preferably, the filter section of the tuned filter can be made such that individual filter circuits are arranged lengthwise such that one filter circuit is closer to the output terminal and another filter circuit is closer to the input terminal. According to one embodiment of the present invention, the tuned filter includes a single circuit board having first and second opposed major surfaces, the opposed major surface being substantially parallel to a single plane and being bisected by a longitudinal axis. An input terminal is connected to the single circuit board with the input terminal having an axis extending substantially parallel to the longitudinal axis. An output terminal is connected to the single circuit board with the output terminal having an axis extending substantially parallel to the longitudinal axis. A filter section is associated with the first major surface. The filter section includes at least two filter circuits, the filter circuits being separated from one another along the longitudinal axis by a first physical shield associated with the first major surface and a second physical shield associated with the second major surface. The first and second shields extending substantially perpendicular to the single plane and the longitudinal axis. A first circuit run extends along the first major surface. The first circuit run has a first end located adjacent one of the filter circuits and has a second end located adjacent another one of the filter circuits. A second circuit run substantially mirrors the first circuit run and extends along the second major surface.

Preferably, the impedances of the input terminal and the output terminal are accurately matched. According to one embodiment of the present invention, the tuned filter includes at least one first terminal circuit run extending along the first major surface matching the impedance of the input terminal and the output terminal, and at least one second terminal circuit run substantially mirroring the first terminal circuit run and extending along the second major surface. According to an alternate embodiment, the tuned filter includes at least two first terminal circuit runs extending along the first major surface matching the impedance of the input terminal and the output terminal, and at least two second terminal circuit runs substantially mirroring the first terminal circuit runs and extending along the second major surface.

### BRIEF DESCRIPTION OF THE DRAWINGS

For a fuller understanding of the nature and objects of the invention, reference should be made to the following detailed description of a preferred mode of practicing the invention, read in connection with the accompanying drawings in which:

FIG. 1 is a sectional view of a tuned filter for selectively passing or blocking RF signals in accordance with the prior art;

FIG. 2 is a chart showing the frequency response of the tuned filter shown in FIG. 1;

FIG. 3 is a sectional view of a tuned filter for selectively passing or blocking RF signals in accordance with the present invention;

FIG. 4 is a perspective view of a lower surface of the tuned filter shown in FIG. 3;

FIG. 5 is a perspective view of an upper surface of the tuned filter shown in FIG. 3;

FIG. 6 is a plan view of the lower surface of the tuned filter shown in FIG. 3;

FIG. 7 is an electrical schematic of a filter circuit used in the tuned filter shown in FIG. 3;

FIG. 8 is an electrical schematic of an alternate filter circuit used in the tuned filter shown in FIG. 3;

FIG. 9 is a sectional view of an output terminal used in the filter shown in FIG. 3;

FIG. 10 is a chart showing the frequency response of the tuned filter shown in FIG. 3;

FIG. 11 is a perspective view of a lower surface of a second embodiment of the present invention;

FIG. 12 is a perspective view of an upper surface of the tuned filter shown in FIG. 11;

FIG. 13 is a sectional view of a fourth embodiment of the present invention;

FIG. 14 is a sectional view of a fifth embodiment of the present invention;

FIG. 15 is a perspective view of an upper surface of a third embodiment of the present invention;

FIG. 16 is a plan view of a lower surface of the tuned filter shown in FIG. 15; and

FIG. 17 is a chart showing the frequency response of the tuned filter shown in FIG. 15.

### DETAILED DESCRIPTION OF THE INVENTION

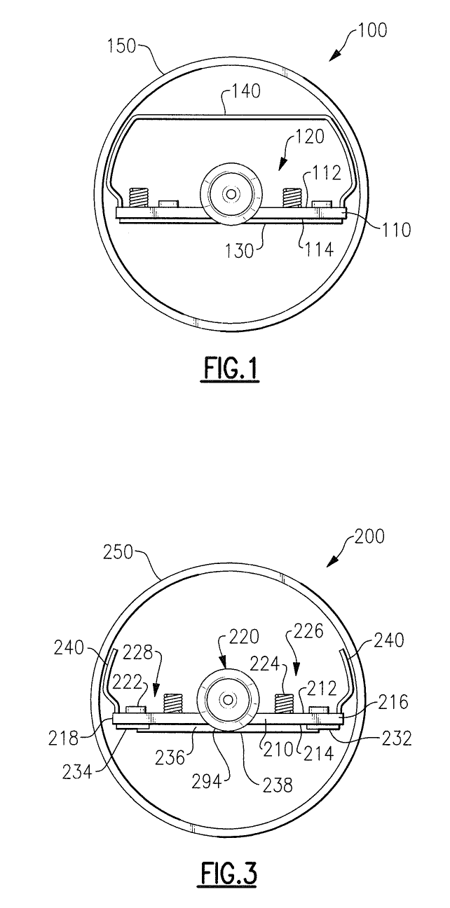

FIG. 1 shows a tuned filter 100 according to the prior art. The tuned filter 100 contains a circuit board 110 having a first major surface 112 and a second major surface 114, A filter section 120 is provided on the first major surface 112, and a solid ground plane 130 is provided on the second major surface 114. The ground plane 130 is electrically connected to a grounding strap 140 that functions to electrically connect the ground plane 130 to an enclosure 150. The ground plane 130 and the ground strap 140 work to dissipate parasitic signals so that signals produced by certain individual components of the filter section 120 remain isolated from signals from other components in the filter section 120. In the case of the tuned filter 100, which includes two or more parallel filter circuits in the filter section 120, a solid ground plane 130 is used to improve isolation between these circuits and minimize the need for other forms of isolation shielding, which can become costly.

The inventors have found that while the ground plane 130 is advantageous for the overall function of the filter section 120 of the tuned filter 100, the ground plane 130 becomes a large detriment when signals having a frequency higher than 1 GHz are passed through the tuned filter 100. As mentioned above, signals having high frequencies, such as those greater than 1 GHz, are easily attenuated through parasitic or fringe capacitance created between components of the filter section 120 and the ground plane 130, the ground straps 140, and the enclosure 150. Along these lines, the inventors have determined that the solid ground plane 130 and the placement of the components of the filter section 120 in relation to the solid ground plane 130 cause significant signal parasitic or fringe capacitance, which, in turn, causes significant deterioration of the tuned filter's 100 ability to pass signals having a frequency greater than 1 GHz. Accordingly, parasitic or fringe capacitance that could be tolerated in tuned filters 100 operating with frequencies below 1 GHz could no longer be tolerated in tuned filters operating above the 1 GHz threshold.

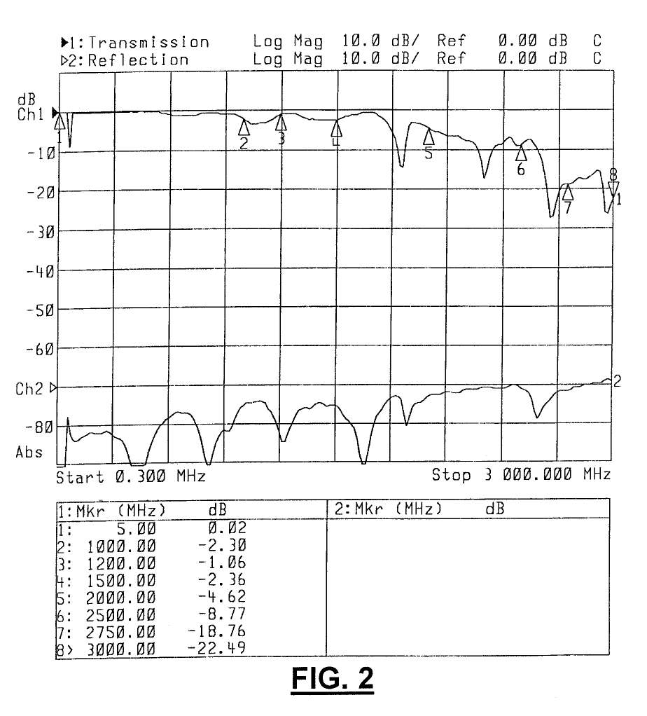

FIG. 2 is a chart showing the high pass frequency response of the tuned filter 100 of the prior art. It should be evident that the tuned filter 100 demonstrates little attenuation up to 1 GHz (1000 MHz), but shows significant signal attenuation in the frequency ranges above 1 GHz.

FIGS. 3, 4, 5 and 6 show a tuned filter 200 in accordance with one embodiment according to the present invention. The tuned filter 200 contains a circuit board 210 having a first major surface 212 and a second major surface 214. An output terminal 294 and an input terminal 292 are provided at opposing ends of the circuit board 210 and extend along a centerline 252 of an enclosure 250. A filter section 220 is placed on the first major surface 212, and can include one or more separate filter circuits 226, 228. Each filter circuit 226, 228 of the filter section 220 typically includes one or more capacitors 222 and inductors 224 connected to one another to allow RF signals having a frequency above a set frequency to pass (high pass) or to allow RF signals having a frequency below a set frequency to pass (low pass). As is well known in the art, various combinations of high pass filter circuits and low pass filter circuits can be assembled into the filter section 220 of the tuned filter 200 to result in a band reject, a high pass, a low pass and/or a bandpass tuned filter.

While the specific combination of capacitors 222 and inductors 224 is important to the desired effect of the tuned filter 200, important aspects of the present embodiment lie in the placement of a first ground path 232 and a second ground path 234 in relation to the circuit board 210, the individual capacitors 222 and inductors 224. As described above in relation to FIG. 1, all of the components of the filter section 120 of the tuned filter 100 are mounted on the first opposing surface 112 opposite a portion of the solid ground plane 130 since it is substantially continuous across the second major surface 114 of the circuit board 110. It has been found however, that the parasitic or fringe capacitance effects in the tuned filter 200 in accordance with the present invention can be substantially reduced if only those discrete components that are to be directly connected to a ground be physically connected to and located directly opposite to one of the ground paths 232, 234.

Since the majority of the parasitic or fringe capacitance effects of the ground plane and the relative proximity of the ground plane to the individual components of the filter section 220 is capacitive, the parasitic or fringe effects caused by mounting the capacitors 222 in close proximity to the ground plane would be minimal. The parasitic or fringe capacitance caused by the proximity of the ground plane to the inductors 224 of the filter section 220 is substantial such that the inductors 224 can create a reactive effect (resonance) that severely degrades any signals in the 1 GHz to 3 GHz bandwidth.

With respect to the embodiment of the present invention shown in FIGS. 3, 4, 5 and 6, the first filter circuit 226 and the second filter circuit 228 of the filter section 220 are arranged such that each falls on opposing sides of a longitudinal axis 254 of the circuit board 210. The first ground path 232 and the second ground path 234 located, respectively, directly opposite the majority of the capacitors 222 of the first filter circuit 226 and the second filter circuit 228. In furtherance to the findings of the inventors, the inductors 224 are located on the first major surface 212 opposite a portion of the second major surface 214 where the two ground paths 232, 234 are not solidly present.

Specifically, the first ground path 232 is provided along a first opposing side 216 of the circuit board 210, and the second ground path 234 is provided along a second opposing side 218 of the circuit board 210. This arrangement allows for a space 236 separating the ground paths 232, 234 along the longitudinal axis 254 of the circuit board 210. It should be understood that the two ground paths 232, 234 may connect one another at some point along the circuit board 210 through trace (not shown) extending along the second major surface 214 of the circuit board 210 or through some other minimal connection. This connection should be kept, however, to a minimum allowing the space 236 to be as large as possible while retaining the ground paths 232, 234.

As asserted in further detail above, the maximum benefits are achieved when all of the capacitors 222 in the filter section 220 are placed on the first major surface 212 opposite the ground paths 232, 234 and all of the inductors 224 in the filter section 220 are placed on the first major surface 212 opposite the space 236. It should be noted, however, that because of space constraints on the relatively small circuit board 210, some capacitors 222 may have to be placed over the space 236 and some of the inductors 224 may have to be placed over the ground paths 232, 234. These deviations should be kept to a minimum, as long as other design considerations, such as spacing requirements, are able to be met.

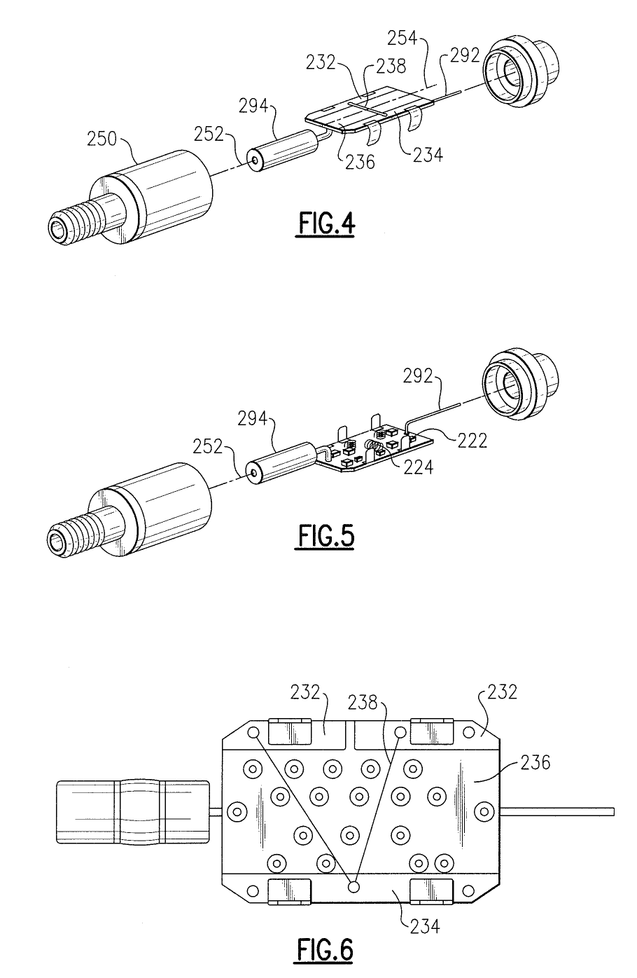

Optionally, an inductive contact 238 can be included to electrically connect the first ground path 232 and the second ground path 234. As shown in FIGS. 3 and 4, the inductive contact 238 in the present embodiment is a pair of 28 ga wires. Both wires of the inductive contact 238 are connected at a single location on the first ground path 232 and divergently extend toward the second ground path 234 such that the inductive contact is attached to the second ground path at two locations. The inductive contact 238 allows for increased isolation between the first filter circuit 226 and the second filter circuit 228. It should be understood that the inductive contact can take the form of a metallic trace connecting the two ground paths 232, 234 across either the first major surface 212 or the second major surface 214. Further, it should be understood that the inductive contact 238 should be sized only to such a degree that the necessary amount of isolation is achieved, because the size of the inductive contact directly increases the amount of parasitic or fringe capacitance created in the tuned filter 200.

Ground clips 240 are attached to the circuit board 210 and are electrically connected to each of the two ground paths 232, 234. The ground clips 240 include a portion having a curvature that corresponds to the internal surface of the enclosure 250 so that the ground straps 240 can make a solid electrical contact with the enclosure 250. The ground clips 240 of the present embodiment can be automatically provided, inserted or staked onto the circuit board 210. The ground clips 240 must be large enough to support the circuit board 210 and the components mounted thereon. However, the ground clips 240 of the present tuned filter 200 are small enough that they do not take up space within the enclosure 250 over the first major surface 212. This is a benefit in that individual components of the filter section 220 located on the first major surface 212 remain unobstructed, allowing z-axis placement of all of the individual components of the filter section 220. This feature also allows the filter section 220 to be made shorter along the longitudinal axis 254 of the circuit board 210. In the present embodiment, the width of the each ground clip 240 is at least 0.070″ to provide a solid electrical connection with the enclosure 250. This value is based on using material for the ground clips 240 that is approximately 0.010″ thick highly conductive material such as phosphor bronze. These size and material requirements are determined based on the material's skin RF effect at frequencies greater than 1 GHz.

It should be understood that the ground attached between the circuit board 210 and the enclosure 250 may have a form different from the ground clips 240 shown in FIGS. 3, 4 and 5. For example, the ground may take the form of a shield, solder, strap, post or boss. The ground may also be a direct or clinched connection. It is important, however, that each of the grounds has a connection with the circuit board of at least 0.007 in² per ground.

To further improve the stability of the components and the reliability of the tuned filter 200, the entire enclosure 250 can be filled with polyurethane foam potting material (not shown). The use of the polyurethane foam can be added to the assembly once the tuning of the filter section 220 is complete and the enclosure 250 is placed around the assembly. The polyurethane foam provides physical support for the individual capacitors 222 and inductors 224 to ensure that the tuned filter 200 does not fail to function as desired if it is dropped or shaken during installation and use. The foam also helps to repel environmental elements that could corrode the device allowing it to fail. It should be understood that other well-known potting materials may be used with similar success.

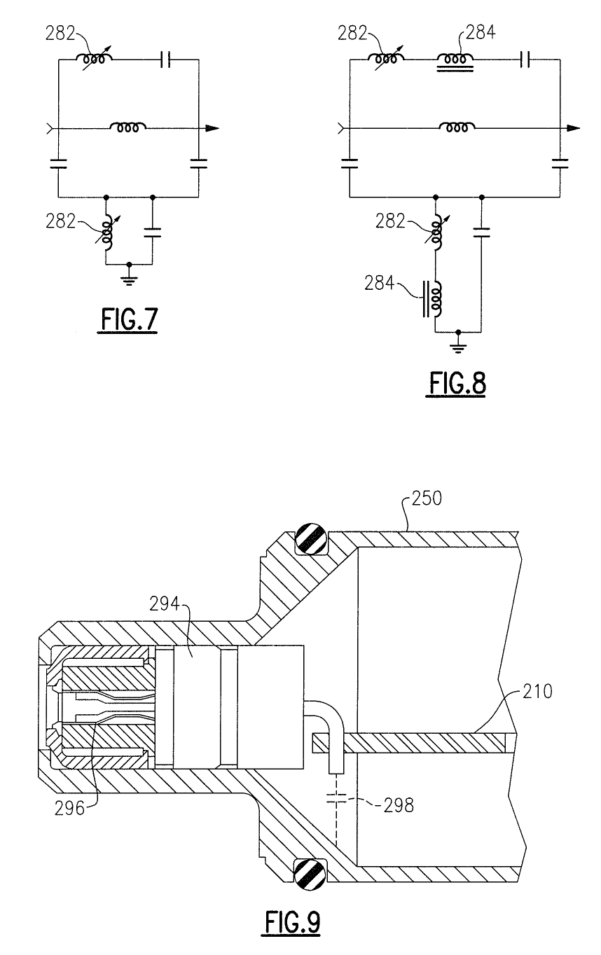

FIGS. 7 and 8 show wiring diagrams relevant to each of the filter circuits 226, 228 of the filter section 220. The inductors 224 in the filter section 220 can be modified in an effort to reduce the occurrence of re-resonance, which directly affects the ability of the tuned filter 200 to pass signals having a high frequency. The inductors 224 can take the form of an air wound inductor 282 and a wirewound chip inductor 284. The inventors have found that the air wound inductors 282 become physically large and resonate when the wire length approaches ½ wavelength length. This resonance causes multiple resonances in higher frequencies (i.e. 1 GHz and above). The inventors have further found that using the wirewound chip inductor 284 in combination with a smaller version of the air wound inductor 282, as shown in FIG. 8, limits the multiple resonances in the higher frequencies. Further, the inventors determined that the ferrite core material of the wirewound chip inductor 284 is resistive at higher frequencies such that any multiple resonances caused by the length of the wire in the wirewound chip inductor 284 are dampened making the effect of the multiple resonances negligible in the higher frequency spectrum. The air wound inductor 284 is preferably retained, however, in a smaller form to allow the circuit to be accurately tuned at the time of manufacture.

The output terminal 294 of the tuned filter 200 contains a contact seizure assembly 296 (FIG. 9) that must be able to accept a pin size that varies from 0.020″ to 0.047″. This ability to accept such a wide range of pins causes the impedance of the connector assembly to be mismatched. This mismatch is primarily capacitive within a coaxial portion of the connector. By introducing a series inductive impedance at the end of the output terminal 294 adjacent the circuit board 210, and by adding shunt capacitance to ground after the inductive line, there is formed a lowpass matching network. The inductance can be made by many different methods. For example, one way would be to increase the outer conductor size, while another way would be to add a physical inductor. In the same way, the shunt capacitance can be added by such as by varying the pad size on the circuit board 210, and another way would be to add physical capacitors 298. According to this method, the mismatch in impedance can be balanced to further improve the return loss of the output terminal 294 by up to 10 db at 3 GHz.

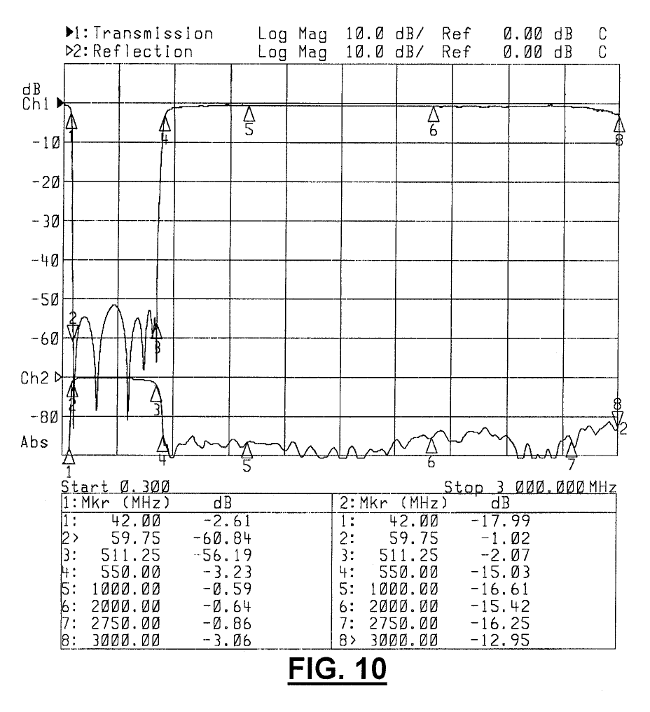

FIG. 10 is a chart showing the high pass frequency response of the tuned filter 200 made in accordance with an embodiment of the present invention. It should be evident that the tuned filter 200 demonstrates little attenuation throughout the frequency band between 1 GHz and 3 GHz, especially when compared to the tuned filter 100 (FIG. 1) of the prior art (see FIG. 2).

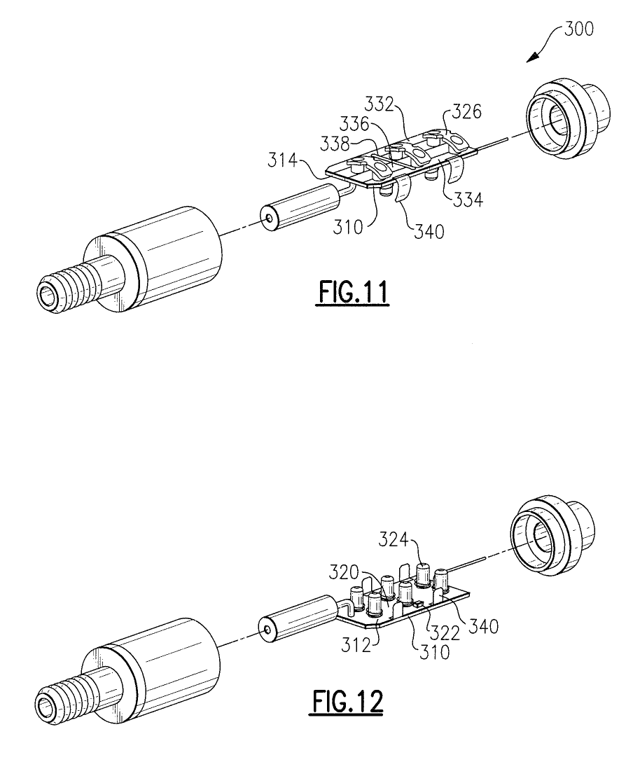

FIGS. 11 and 12 show a tuned filter 300 in accordance with an alternate embodiment according to the present invention. The tuned filter 300 includes a first grounding path 332 and a second grounding path 334 extending along a second major surface 314 of a circuit board 310. The two grounding paths 332, 334 are separated by a space 336 extending along the length of the circuit board 310. An inductive contact 338 in the form of a single wire is used to connect the two grounding paths 332, 334 together. Similar to the previous embodiments, the grounding paths 332, 334, the inductive contact 338 and the space 336 can take on a variety of forms based on the space requirements and the type of signals that are to be filtered.

A filter section 320 is provided on a first major surface 312 of the circuit board 310. The filter section 320 includes tunable inductors 324 and capacitors 322. The tunable inductors 324 include a brass or equivalent slug (not shown) that is passed through a hole 326 to selectively tune the response of the inductor 324. The use of tunable inductors 324 of the sort shown is well known in the art. It should be noted, however, that the inductors 324 of the present embodiment are located on the first major surface 312 opposite the space 336 located on the second major surface 314.

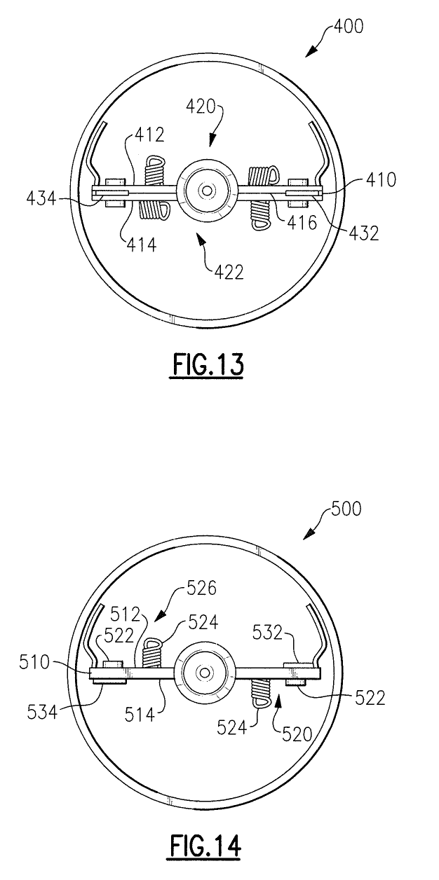

FIG. 13 shows a tuned filter 400 in accordance with an alternate embodiment according to the present invention. The tuned filter 400 includes a single circuit board 410 including a first major surface 412, a second major surface 414, and a third plane 416. A first filter section 420 associated with the first major surface 412 and a second filter section 422 is associated with the second major surface 414, A first ground path 432 and a second ground path 434 are associated with the third plane 416 located between the first major surface 412 and the second major surface 414. The ground paths 432, 434 are separated from one another along the third plane with the exception of optional inductive contacts that electrically contact both ground paths 432, 434. As discussed in connection with other embodiments, the inductive contact can take the form of a trace (not shown) extending along one of the major surfaces 412, 414, along the third plane 416, and/or a conductive wire.

FIG. 14 shows a tuned filter 500 in accordance with an alternate embodiment according to the present invention. A first filter section 520 is associated with a second major surface 514 of a circuit board 510, and a second filter section 526 is associated with a first major surface 512 of the circuit board 510. A first ground path 532 is associated with the first major surface 512 opposite a portion of the first filter section 520, and a second ground path 534 is associated with the second major surface 514 opposite a portion of the second filter section 526. Each filter section 520, 526 preferably includes a plurality of discrete capacitors 522 and a plurality of discrete inductors 524. Similar to the embodiments discussed above, it is preferable, but not required, that the capacitors 522 are located opposite their respective ground path 532, 534, while the inductors 524 are not located in such a manner. To overcome isolation problems associated with not providing ground plane covering an entire major surface, the grounding paths 532, 534 are connected to one another with an inductive thickness (not shown). Connecting the ground planes 532, 534 in this manner improves the isolation between the filter sections 520, 526 while helping to eliminate the parasitic or fringe capacitance created by the components in filter section 520 and/or filter section 526.

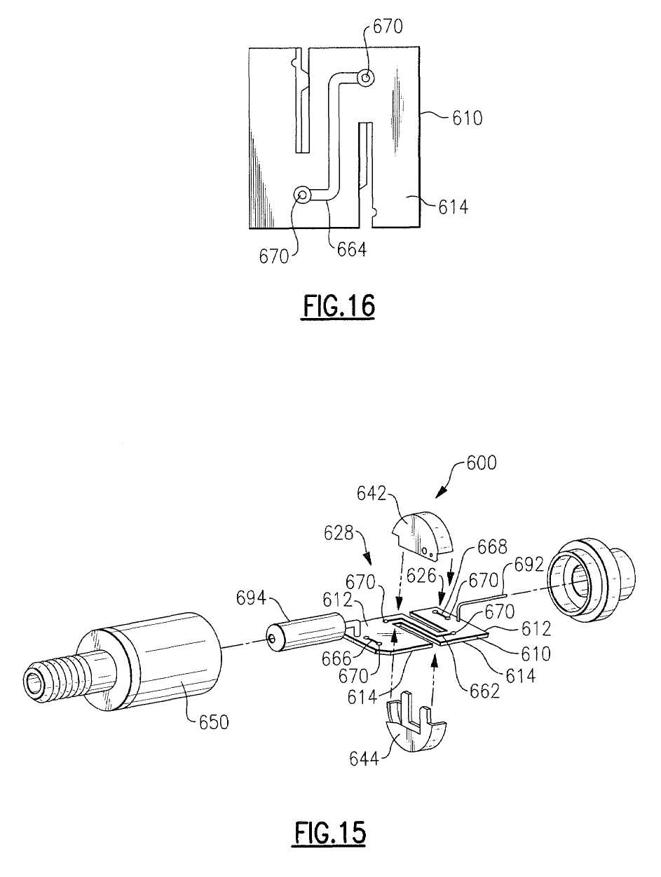

FIGS. 15 and 16 show a tuned filter 600 in accordance with an alternate embodiment according to the present invention. The tuned filter 600 includes a first filter circuit 626 and a second filter circuit 628 located on a first major surface 612 of a circuit board 610. The first filter circuit 626 and the second filter circuit 628 are separated from one another by at least one shield. As shown in FIG. 15, the shield can have two portions, a first shield portion 642 and a second shield portion 644.

As with the ground plane used in the embodiments described above, the first shield portion 642 and the second shield portion 644 increase parasitic or fringe capacitance that create a parasitic attenuation on high frequency signals (i.e., greater than 1 GHz) passed through the tuned filter 600. To overcome the attenuation of the high frequency signals, a first circuit run 662 is placed on the first major surface of the circuit board 610 and a mirror image second circuit run 664 is placed in parallel to the first circuit run 662 on a second major surface 614 of the circuit board 610. The first circuit run 662 and the second circuit run 664 are interconnected to one another via plated through holes 670 at each end the circuit runs 662, 664. It should be understood that the plated through holes 670 can take the form of any electrical connection that passes through the circuit board, as is well known in the art. The use of the first and second parallel circuit runs 662, 664 effectively reduce the inductive component of entire run by a factor of two, which improves the high frequency response of the tuned filter 600. As one skilled in the art can readily understand, first circuit run 662 and the second circuit run 664 can be shaped differently from one another without affecting the function and the benefits achieved by placing one run on each of the major surfaces 612, 614 of the circuit board 610.

Along these lines, any series inductance required to match the impedance of an input terminal 692 and an output terminal 694 can be reduced by adding additional terminal circuit runs 666, 668 on the first major surface 612 and mirror image circuit runs (not shown) on the second major surface 614. While the terminal circuit runs on the second major surface 614 are not shown in FIG. 16, it should be understood that the terminal circuit runs on both major surfaces 612, 614 are connected to one another via plated through holes 670 or similar connection types that are well known in the art.

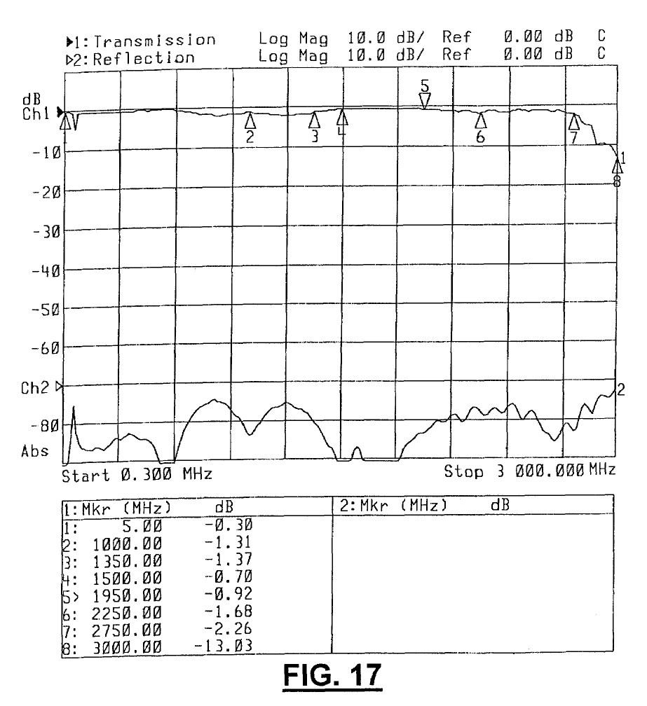

FIG. 17 is a chart showing the high frequency response of the tuned filter 600 made in accordance with an embodiment of the present invention. It should be evident that the tuned filter 600 demonstrates little attenuation throughout the frequency band between 1 GHz and 3 GHz, especially when compared to the tuned filter 100 (FIG. 1) of the prior art (see FIG. 2).

While the present invention has been particularly shown and described with reference to the preferred mode as illustrated in the drawings, it will be understood by one skilled in the art that various changes may be effected therein without departing from the spirit and the scope of the invention as defined by the claims. Additionally, it will be understood by one skilled in the art that the term substantially used herein includes all variances normally associated with mass production techniques and other generally accepted manufacturing tolerances.

What is claimed is:

1. A tuned filter comprising:
a single circuit board having first and second opposed major surfaces and first and second opposing sides, the opposed major surfaces being substantially parallel to a single plane and being bisected by a longitudinal axis, the first and second opposing sides being substantially parallel to the longitudinal axis;
an input terminal connected to the single circuit board, the input terminal having an axis extending substantially parallel to the longitudinal axis;
an output terminal connected to the single circuit board, the output terminal having an axis extending parallel to the longitudinal axis;
a filter section associated with the first major surface;
at least two ground paths associated with the second major surface, one of the ground paths extending along a portion of the first opposing side and another one of the ground paths extending along a portion of the second opposing side;
an isolation region separating the at least two ground paths and extending along the longitudinal axis.

2. The tuned filter of claim 1, further comprising at least one inductive contact connecting the at least two ground paths, wherein the inductive contact spans the isolation region and extends along the second major surface.

3. The tuned filter of claim 2, wherein the inductive contact is a metallic wire.

4. The tuned filter of claim 3, wherein the metallic wire directly contacts the at least two ground paths and has a continuous cross section throughout its length between the at least two ground paths.

5. The tuned filter of claim 3, wherein the inductive contact is arranged at an angle incident to the longitudinal axis.

6. The tuned filter of claim 3, wherein at least two of the inductive contacts are connected to a common point on one of the grounding paths.

7. The tuned filter of claim 1, further comprising a plurality of grounding means attached to the single circuit board along the first and second opposing sides of the single circuit board.

8. The tuned filter of claim 7, wherein at least one grounding means is directly connected to each of the grounding paths.

9. The tuned filter of claim 7, wherein each of the grounding means contacts the circuit board with an area at least 0.007 in².

10. The tuned filter of claim 1, wherein the filter section comprises a plurality of discrete capacitor elements, each capacitor element being associated with the first major surface above a respective ground path.

11. The tuned filter of claim 1, wherein the filter section comprises a plurality of discrete inductive elements, each discrete inductive element being associated with the first major surface above the isolation region separating the at least two ground paths.

12. The tuned filter of claim 11, wherein at least one of the inductive elements is an air wound inductor, and at least one of the inductive elements is a wirewound chip inductor connected in series with the airwound inductor.

13. The tuned filter of claim 11, wherein at least one of the inductive elements comprises tuning means for varying the inductance of the inductive element.

14. The tuned filter of claim 13, wherein the tuning means is actuated along a direction perpendicular to the first and second major surfaces.

15. The tuned filter of claim 1, further comprising a conductive housing encircling the single circuit board, the output terminal, and the input terminal, the conductive housing being electrically connected to each of the ground paths.

16. The tuned filter of claim 15, wherein the conductive housing is cylindrical, and a central axis of the cylinder is substantially parallel with the longitudinal axis of the single circuit board.

17. The tuned filter of claim 1, further comprising series inductive impedance located at an end of the output terminal adjacent the circuit board and a shunt capacitance to ground after the inductive impedance.

18. The tuned filter of claim 17, wherein the series inductive impedance is one of an increased outer conductor size and an additional physical inductor.

19. The tuned filter of claim 17, wherein the shunt capacitance is one of an increased pad size of the output terminal on the circuit board and at least one physical capacitor.

20. A tuned filter comprising:
a single circuit board having first and second opposed major surfaces and first and second opposing sides, the opposed major surfaces being substantially parallel to a single plane and being bisected by a longitudinal axis, the first and second opposing sides being substantially parallel to the longitudinal axis;
an input terminal connected to the single circuit board, the input terminal having an axis extending substantially parallel to the longitudinal axis;
an output terminal connected to the single circuit board, the output terminal having an axis extending substantially parallel to the longitudinal axis;
a filter section associated with the first major surface, the filter section comprising at least two filter circuits with one filter circuit associated with one side of the longitudinal axis and another filter circuit associated with an opposing side of the longitudinal axis, each circuit having a plurality of capacitors, at least one air wound inductor, and at least one wirewound chip inductor, the air wound inductor and the wirewound chip inductor being connected in series with one another;
at least two ground paths associated with the second major surface, one of the ground paths extending along a portion of the first opposing side and another one of the ground paths extending along a portion of the second opposing side;
an isolation region separating the at least two ground paths, and extending along the longitudinal axis; and
at least one inductive contact connecting the at least two ground paths, the inductive contact being one of a metallic wire and a metallic trace on the circuit board,
wherein the inductive contact spans the isolation region and extends along the second major surface.

21. A tuned filter comprising:
a single circuit board having first and second opposed major surfaces, the opposed major surfaces being substantially parallel to a single plane and being bisected by a longitudinal axis;
an input terminal connected to the single circuit board, the input terminal having an axis extending substantially parallel to the longitudinal axis;
an output terminal connected to the single circuit board, the output terminal having an axis extending substantially parallel to the longitudinal axis;
a filter section associated with the first major surface, the filter section comprising at least two filter circuits, the filter circuits being separated from one another along the longitudinal axis by at least one first physical shield associated with the first major surface and at least one second physical shield associated with the second major surface, the first and second shields extending substantially perpendicular to the single plane and the longitudinal axis;
a first circuit run extending along the first major surface, the first circuit run having a first end located adjacent one of the filter circuits and having a second end located adjacent another one of the filter circuits; and
a second circuit run substantially mirroring the first circuit run and extending along second major surface.

22. The tuned filter of claim 21, further comprising at least one first terminal circuit run extending along the first major surface matching the impedance of the input terminal and the output terminal, and at least one second terminal circuit run substantially mirroring the first terminal circuit run and extending along the second major surface.

23. The tuned filter of claim 21, further comprising at least two first terminal circuit runs extending along the first major surface matching the impedance of the input terminal and the output terminal, and at least two second terminal circuit runs substantially mirroring the first terminal circuit runs and extending along the second major surface.

24. The tuned filter of claim 21, wherein the first and second shields are a single piece of material.
